(19) United States
(12) Patent Application Publication
(10) Pub. No.: US 2004/0133529 A1
(43) Pub. Date: Jul. 8, 2004

(54) Method and system of coordination of consumption and/or production in distribution systems

(76) Inventor: Ebbe Munster, (US)

Correspondence Address: CANTOR COLBURN, LLP, 55 GRIFFIN ROAD SOUTH, BLOOMFIELD, CT, 06002

(21) Appl. No.: 10/468,187

(22) PCT Filed: Feb. 15, 2002
(86) PCT No.: PCT/DK02/00108

(30) Foreign Application Priority Data
Feb. 15, 2001 (DK) PA2001 00258

(51) Int. Cl. G06F 17/60; G01R 11/56; G06F 17/00

(52) U.S. Cl. 705/412; 705/7; 705/10

(57) ABSTRACT

Method of use in relation to control of production and/or consumption in a distribution system, 1, of for example heat, electricity, gas, water etc., or in a system or associated systems comprising at least one producer or distributor, 3, and one or more consumers, 2. By the invention, information of importance to the consumption and/or production, for example prognoses of prices, consumption or the like, is provided to one or more of said consumers, 2, producers and/or suppliers, 3, and said information is used to control production, delivery and/or consumption.

### USE OF THE INVENTION

The present invention relates to a method of use in relation to control of production and/or consumption in a distribution system of for example heat, electricity, gas, water etc., or in a system or associated systems comprising at least one producer or distributor and one or more consumers.

The invention also relates to systems and methods of use in relation to which the invention may be utilized.

### BACKGROUND OF THE INVENTION

Systems facilitating communication between utility companies and consumers/producers over the phone net/mobile telephone net or other radio frequencies are known. Previously, it has also been suggested to use such systems for establishment of “load management” by utilizing tariff structures with varying time limits and the possibility to disrupt consumption/production.

Thus, U.S. Pat. No. 6,006,085 and U.S. Pat. No. 5,974,308 relate to utilization of a “Variable Charge Rate” which is reported to the mobile telephone users by means of SMS on a current basis with the aim of evening out the strain on the mobile phone net over the entire day. Only the current price is reported together with for example the period during which the price is offered. The consumer must read the price information manually and decide whether to take advantage of it or not. Thus, utilization will be non-systematic and random.

U.S. Pat. No. 4,213,182 and U.S. Pat. No. 3,906,242 relate to systems for communication with consumers of electricity which may be cut off. In Norway, a similar system is marketed under the name of Ebox. by the company Elink AS in cooperation with Statoil. These systems are controlled centrally and cannot take into account the current situation of the individual consumer.

U.S. Pat. No. 4,247,786 relates to a system involving remote control of power limiters at the individual electricity consumers or groups thereof. The method resembles that of disruptable electricity consumption and suffers from the same drawbacks.

U.S. Pat. No. 5,420,799 relates to a system for remote instrument readings of energy indicators. Such a system is also provided by TeleDanmark under the name of TeleLink. It uses either regular phone lines (in such a manner that regular phones are not disrupted) or GSM phone connections. Apart from carrying out readings, the system may also be used for monitoring, since alarms triggered by the consumers may be handled by the system. The system does not involve control of consumption or production by the consumers.

Furthermore, it is possible in the USA today to order electricity to be delivered in for example 3 hours on the basis of a price charged by the hour on the internet (for example the APX system in California). On the internet, it is also possible to subscribe to prognoses for the days to come (for example by means of the company RER in San Diego, Calif.). The above-mentioned internet-based services are designed to provide the decision-makers of large consumers with information that may be used to make purchasing decisions. They are not used directly to control consumption or production.

Furthermore, GB 2 309 567 A relates to various embodiments for consumption or production-associated systems using a data network for transmission of current energy prices, i.e. the price at the time of transmission, and potentially meteorological data on the basis of which potential automated control of production and consumption may be carried out. However, such prognoses are not transmitted in relation to prices which is also the reason why control by this known system cannot take place with reference to future price conditions.

Finally, a method of energy distribution is known from EP 1 003 265 A1 which uses a “bidding and reservation system” by means of which the tariffs are reported to the consumers. With this known method, two types of tariffs are reported for a limited period of time, i.e. a regular tariff and a penalty tariff. The consumers may then report back with the amount of electricity they expect to consume during the period of time in question. The distributors may then accept offers which they find relevant and subsequently estimate the demand during that particular period in time. If the consumer uses the amount agreed upon, the normal tariff is charged whereas the penalty tariff is charged, if he uses less than agreed upon.

By means of this “auction system”, time-dependant tariffs are agreed upon with the individual consumer for a future limited period of time (typically 24 hours) which limits the consumer's ability to use this system to control consumption of electricity and thus the costs associated therewith. Furthermore, the system has the drawback that two-way communication between the consumers and the distributors is required.

Thus, it is an object of the invention to introduce an improved method and an improved system for coordination of consumption of electricity, energy, water, heat, gas and similar consumer goods by means of which the above-mentioned, known system drawbacks may be avoided.

Furthermore, it is an object of the invention to introduce such a method and such a system that the individual units—whether relating to consumers or producers—have the opportunity to plan an optimal strategy for consumption or production. Also, it is an object of the invention to introduce a method and a system allowing for an optimal strategy which may be more or less automated.

In addition, it is an object of the invention to introduce a method and a system making it possible on a qualified basis to prepare an actual long-term plan for consumption and/or production of electricity, energy, water, heat, gas and similar consumer goods.

Also, it is an object of the invention to introduce a method and a system that allow for increased utilization of flexibility during consumption and production/distribution of the said consumer goods.

These and other objects are obtained by the invention as will be illustrated in the following.

### THE INVENTION

The invention relates to a method of establishing improved coordination between the consumption and production of electricity, heat, water or the like in a distribution system, said method being characterized by the characterizing measures specified in claim 1. It involves communication between a central unit and a number of consumers and/or producers associated with the distribution system. Communication may be one-way or two-way and may take place via a modem or via wireless connections.

As specified in claim 1, the invention relates to a method of utilization in relation to the control of production and/or consumption in a distribution system of for example heat, electricity, gas, water etc. in a system or associated systems comprising at least one producer or distribution and one or more consumers.

According to the invention, this method is characterized by providing information, incl. for example purchase and/or sales prices or prognoses thereof, tariffs etc. of importance to the consumption and/or production, said information being made available to said one or more consumers, producers and/or distributors, and said information being used to control production, distribution and/or consumption, and said information comprising

actual and/or determined data concerning a first period of time, and

expected, calculated and/or estimated data concerning a second period of time,

said first period of time being identified as the period of time following immediately after the time of consumption or production, and said second period of time extending beyond the first period of time.

Thus, it will be possible to transmit prognoses for time-dependent tariffs which will make it possible, shortly before the consumption situation or the operating minute so to speak, to determine or announce the actual tariff(s) concerning said first period of time. This first period of time may be as limited as for example 15 minutes and may last for a couple of hours or longer depending on the situation at hand and the circumstances in question.

Also, prognoses for the said second period of time which lasts significantly longer than for example 24 hours, such as 5 days or more, may be made available so that the consumers will have the opportunity to carry out long-term planning, preferably in an automated manner. It should be noted that said prognoses will require regular updates at short or long intervals, said intervals potentially being dependent on other circumstances such as the time of day, time of year the weather conditions etc. In this manner, the consumer will have the advantage of an improved basis for decision making as the operating minute draws closer.

A central unit, such as a central unit for distribution of energy or another consumer good, will have the unique advantage of being able to utilize the flexibility of both consumers and producers and/or distributors for regulations at relative short notice without having to initiate a troublesome and expensive process involving the signature of agreements with these concerning the rights to be able to remote-control the individual units at the consumers and the producers/distributors in a dictated manner. It should also be noted that a significant aspect of the invention is that the price prognoses announced by the central unit will not be binding which makes it possible to announce these prognoses for a sufficiently long period of time so that consumers have the opportunity to make long-term plans. Correspondingly, the central unit will obtain a desired flexibility level all the way up to shortly before the operating moment, since the announcements concerning price prognoses will not be binding.

According to the invention, such a central unit may also have its requirements for regulations and balancing covered at least partly from a technical point of view in order to avoid for example breakdowns of the system, and from a financial point of view, to avoid having to buy or sell electricity to others at unfavourable periods in time and/or terms.

Furthermore, the resulting joint control of a system using a method according to the invention will be improved since the individual consumers/producers may take local conditions into consideration during the planning process which would be impossible or at least unnecessarily troublesome to handle for a central unit unit.

Furthermore, the consumers and the producers/distributors using the invention would be awarded for their flexibility. It is obvious that the effect of the invention presupposes a certain flexibility on the part of the consumers/producers/distributors but they would also obtain great advantages in terms of e.g. more favourable average prices in order to encourage them to utilize the invention and its facilities.

The novelty of the invention is to expand information transmitted to the consumers and the decentral producers so that it comprises information of not only the immediate price, but also of determined or expected developments in prices for a short or long future periods of time. It could for example involve 5-day-prognoses for purchase and sales prices for electricity and—especially for the combined heat- and power plants—a 5-day-prognosis for estimated consumption of heat. If the prognoses comprise e.g. the expected prices on an hourly basis divided into 64 levels, the amount of data would be so small that the prognosis may be contained in a GSM-SMS message. This also applies to heating prognoses and other requirement prognoses.

The prognoses must then be updated on a current basis, for example so that the prognosis for the next 12 hours is updated every half an hour while the rest of the prognosis is only updated for example twice a day. Private consumers, who are only connected through a normal phone line, could for example do with as little as two updates a day.

As mentioned, the advantage of such a system consists of the individual units, whether they represent consumers or producers, being provided with the opportunity to plan an optimal strategy in terms of consumption or production. The planning of strategy may then be more or less automated.

In terms of combined heat- and power plants, it will be possible to let such information form part of the automated operating schedule taking place in the SRO computers of the plant (SRO is short for Control, Regulation and Monitoring in Danish). Thus, it will be possible for the electricity companies to adapt the variation in the purchase prices on electricity in such a manner that the regulation capacity of the combined heat- and power plants is utilized in an optimal manner. If the parties can agree (if the price is right), the system may be expanded and the electricity companies be offered the possibility to directly initiate/terminate activity in the plants.

In the embodiment of the invention specified in claim 2, said information comprises time-sequential information which is a function that relates to the determined or expected development in sales prices for a well-defined part of the future.

In the embodiment of the invention specified in claim 3, said information comprises time-sequential information which is a function that relates to the determined or expected development in purchase prices for a well-defined part of the future.

Conveniently, as specified in claim 4, said information comprises time-sequential information which is a function that relates to meteorological parameters of importance to the planning by the producers or consumers for a well-defined part of the future. Thus, weather conditions influencing for example the consumption of electricity for cooling or heat consumption associated with combined heat- and power plant production etc. may be taken into consideration.

In a particularly advantageous embodiment, as specified in claim 5, said information is utilized by one or more of said consumers for time-dependent control of switching-on and/or regulation of consumption for one or more units at each consumer.

In this manner, it is possible for the private consumer to let control of the individual consumer units take place in a fully automated manner. For example, deep freezers may be introduced on the market with a two-step thermostat: a max. temperature which must be maintained irrespective of the tariff and a lower temperature to which the freezer cools down during periods with low tariffs.

A washer (or an external relay box for the machine) may start when the price is low and when the prognosis says that there is just enough time left to process one load before the price goes up again. She may also choose a solution where the prognosis appears on a small screen (for example a computer on a refrigerator) so that consumption may be planned. A link to the family computer, the TV or a corresponding unit is also possible.

As specified in claim 6, the system may also be expanded to include transmission of service messages to producers and consumers such as alerts of general price increases, information on interruptions due to maintenance etc. This information will for example be available on the above-mentioned displays or be printed out by the SRO computers (Control, Regulation and Monitoring).

Conveniently, as specified in claim 7, said information may be used by one or more of the said producers for time-dependent control of initiation and/or regulation of one or more units at each producer.

In another advantageous embodiment, as specified in claim 8, the time-sequential information, which is a function that relates to determined or expected plans for future consumption, is transmitted from one or more consumers to one central unit.

In yet another advantageous embodiment, as specified in claim 9, the time-sequential information which is a function that relates to determined or expected plans for future production is transmitted from one or more producers to one central unit.

In these further developed systems, producers and consumers of a certain size may transmit the results of their operating schedules back to the central unit in terms of a time-regulator for the determined or expected amounts of production or consumption for an extensive or less extensive part of the future. This will improve the central unit's ability to predict the load development on the net and thus result in an iterative process.

As specified in claim 10, one or more of said consumers may also be producers/distributors and the mentioned advantages may also be obtained when utilizing the method according to the invention in these relatively complicated control situations.

In addition, as specified in claim 11, the invention also relates to a system for use in connection with control of production and/or consumption in a distribution system of e.g. heat, electricity, gas, water etc. or in a system or associated systems comprising at least one producer or supplier and one or more consumers, said system being characterized by the system using a method according to one or more of claims 1 to 10.

The invention differs from other existing Power Exchanges by the price variation being created by the market in which many consumers interact with an appropriate number of suppliers. According to the invention, the price variation of a specific supplier is determined on the basis of prognoses of e.g. consumption of electricity, wind production etc. in such a manner that it provides the optimal load profile on the electricity net. In this example, the consumers and the electricity producers are associated with specific suppliers by means of agreements of a certain duration (for example one year).

In this manner, the individual distribution company may channel the advantages that they obtain due to improved distribution of the load on the net (peak shaving) on to the consumers. Consumers and producers who may contribute to the regulation at less costs will naturally be the first to react—in this manner, a local market for regulations will emerge. The supplier on his part may—based on experience—adjust for variations in prices so that the exact desired levelling is achieved. In this manner, the regulation is carried out by the players who can do the best job at the cheapest price.

The difference between the function of for example Power Exchanges and the invention may best be described as follows:

1. With the present known technique, prognoses are not transmitted in a way which makes them suitable for input in automated systems related to operating optimization by the consumers and producers.

2. The price variations on the market—and thus the prognoses therefore—suffer from an inherent time-lag due to the fact that they are associated with a system in which the consumers require time to react upon the announced prices. Today, the necessary time is a minimum of 3 hours. Price variations according to the invention may be adjusted at very short notice, e.g. 15 minutes, depending on the current load on the net, for example due to wind power or other varying production units and/or loads. If a sufficient amount of the connected consumers and producers have the equipment which automatically adjusts to the announced prices, it will be possible to create an effective regulation procedure operating very swiftly.

3. Ideally, a market operating perfectly at all levels will also reflect the requirements for levelling of the load but this is not feasible in practice due to the specific conditions applying to distribution of electricity, heat, water etc. (concessions, utilization rights etc.). Thus, the differences between the price variations formed on the market and the variations providing the best regulation is also affected by other factors than the above-mentioned time-lag.

The suggested method may naturally be combined with the above-mentioned methods:

Consumers which may be cut off

Remote readings

Alarm handling

The invention may take on other variations and the examples mentioned above and below are merely an expression for some of the ways in which the invention may be utilized. Thus, variation possibilities are numerous within the scope of the claims below. Among others, the individual consumers may also be producers and other ways of communication and other distribution systems etc. than those exemplified are naturally also possible which will be obvious to a man skilled in the art.

### FIGURES

The invention has been described in detail in the following with reference to the following figures:

FIG. 1 illustrates a system diagram by means of which transmission of time-sequential future variations of price functions takes place,

FIG. 2 illustrates a system diagram by means of which plans for future consumption and/or production are returned,

FIG. 3 illustrates an embodiment of a central unit according to claim 1,

FIG. 4a illustrates an embodiment of a control system at a consumer, and

FIG. 4b illustrates an alternative embodiment of a control system at a consumer.

### EXAMPLES OF EMBODIMENTS

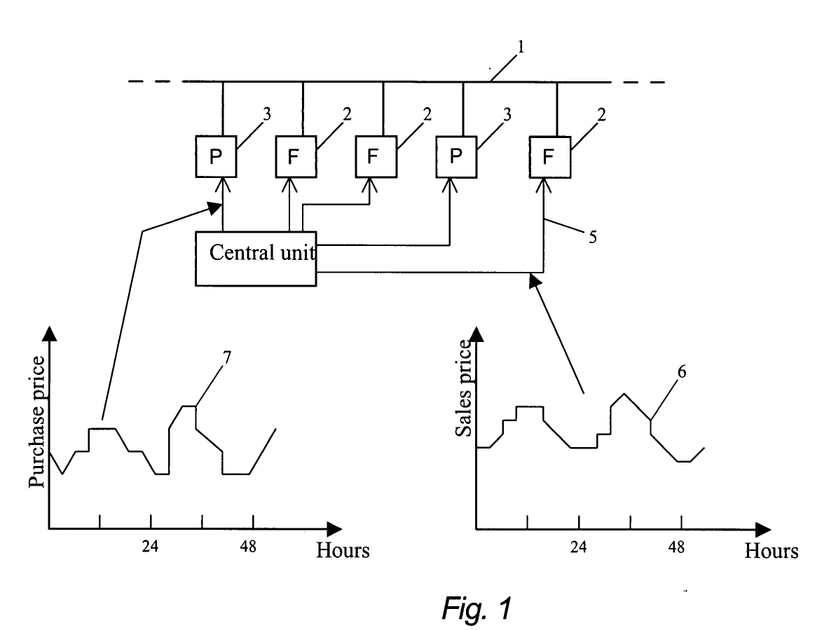

FIG. 1 illustrates a distribution system, 1, for electricity, gas, heat, water or the like.

This system has one or more consumers or groups of consumers, 2, associated herewith together with one or more producers or groups thereof, 3.

A data communication net, 5, which may be implemented as a phone net, a wireless net or the like extends from a central unit, 4, which is typically located in proximity of a large producer, 3. The central unit, 4, transmits time-sequential information, 6, which is a function that relates to the determined or expected development in sales prices for a well-defined part of the future, to the consumers, 2. In the figure, this period lasts for a few days. Similar time-sequential information, 7, which is a function that relates to the determined or expected purchase prices, is transmitted to the producers, 3.

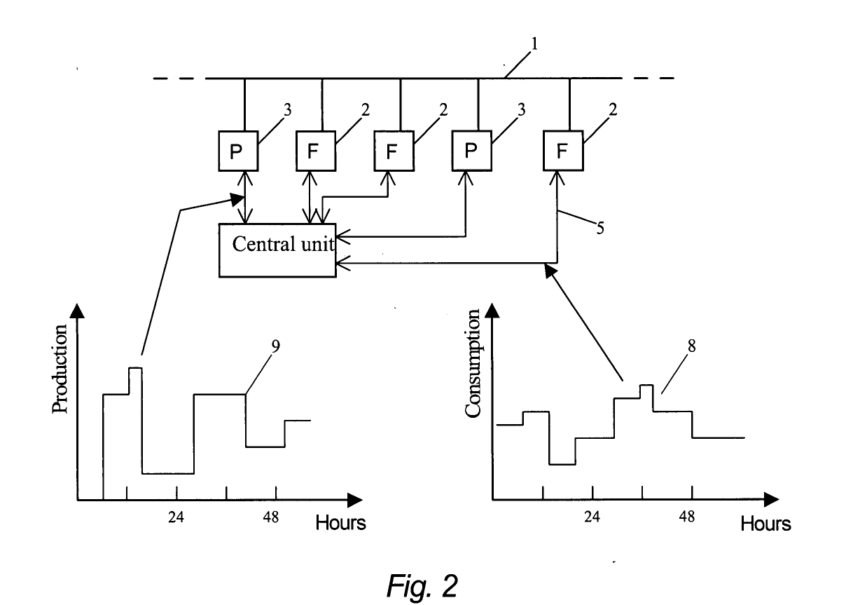

FIG. 2 illustrates a corresponding distribution system, 1, with consumers, 2, and producers, 3. In this system, the time-sequential information from the consumers, 2, and/or the producers, 3, is sent via an information system to the central unit, 4. The consumers—or groups thereof, 2, transmit time-sequential information, 8, which is a function that relates to the individual consumer's determined or expected consumption. The producers—or groups thereof, 3, transmit time-sequential information, 9, which is a function that relates to the determined or expected production.

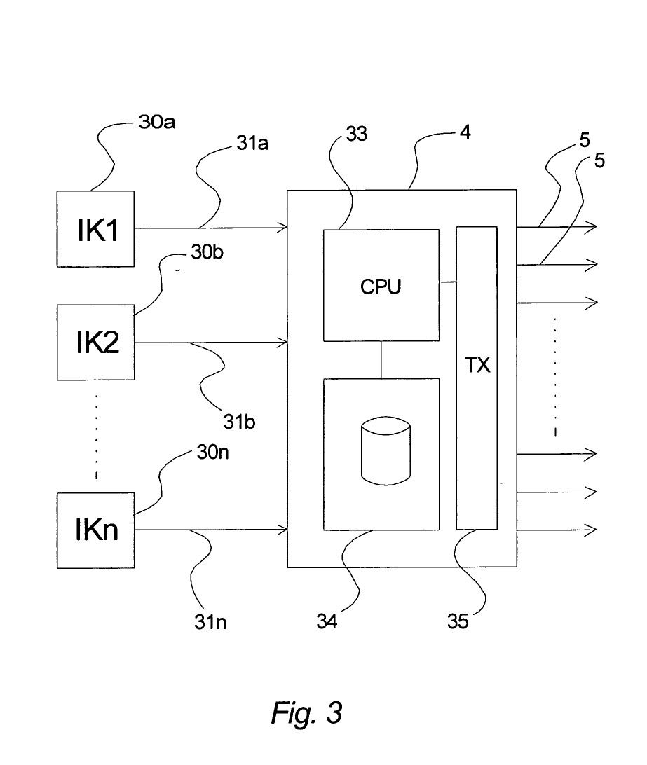

FIG. 3 illustrates an embodiment of a central unit, 4, which may transmit information to consumers 2 and producers 3 via an information system as previously mentioned.

As illustrated, the central unit 4 may receive data, information, etc. from one or more sources of information (IK1-IKN) 30a to 30n, which may transmit these data via communication connections 31a to 31n. These communication connections may be of varying nature such as wired or wireless connections but may also take the shape of information on paper which may eventually be inputted electronically into the central unit 4.

The said data are transmitted to a central unit CPU, for example in the shape of a computer, PC or another form of processor, 33, capable of processing the data and potentially forming prognoses on the basis thereof. The data or the information, prognoses etc. based thereupon may be stored in storage means 34 and may even be transmitted via transmission means (TX) 35 to the consumers/producers who wish to receive the calculated information, prognoses etc.

Transmission of information may be controlled by the unit 33 and potentially on the basis of stored information from the storage means 34 depending on the terms of delivery agreed upon by the individual customer/consumer/producer. These terms may relate to update frequency, nature of information, period for prognosis etc. Furthermore, registration of received information may be made by means of the unit 33 with the object of charging the individual consumer if this forms part of the agreement. Transmission may take place in every imaginable manner as previously mentioned.

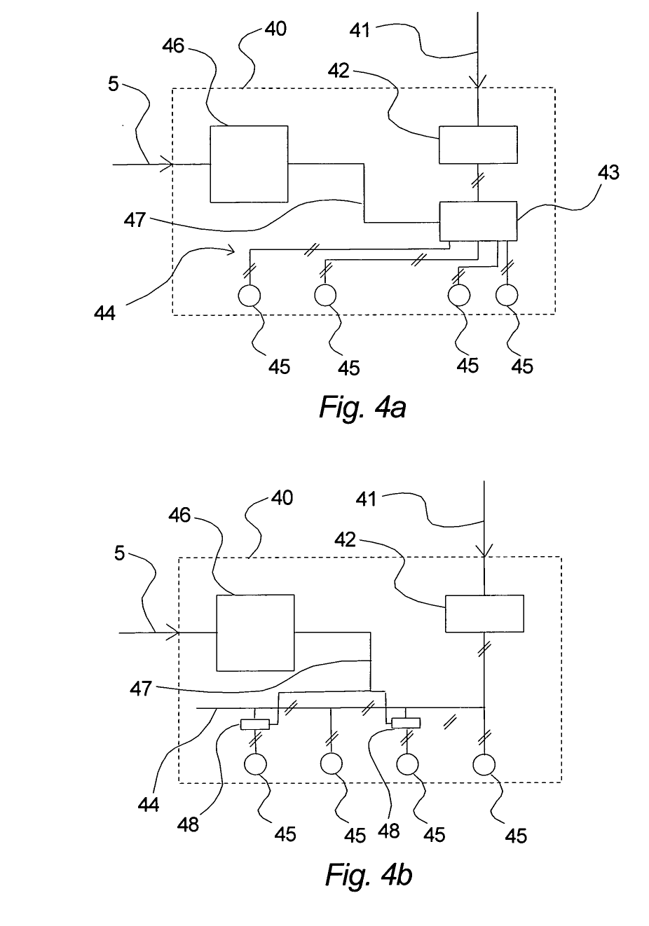

FIG. 4 illustrates examples of how the transmitted data/information may be utilized by the individual consumer 40.

FIG. 4a illustrates a consumer installation which is generally referred to as 40. A supply unit 41 has been connected herewith, for example in the form of a 2, 3, 4 or 5 conductor power supply which is commonly known. This is connected to a meter or fuse box 42 from which there is a connection to a control unit 43, according to this embodiment of the invention, which may e.g. comprise relay control or the like. From here, wires 44, which may be twin core cables, but may also have a any other number of conductors, lead to the individual consumer locations 45.

Data is transferred to the installation 40 via the information system 5 to a receiver and control unit 46 which may comprise for example a micro processor or the like. From here, control signals are transmitted via the signal wires 47 to the control unit 43 which may then control the supply to the consumer locations 45 individually, in groups or collectively.

FIG. 4b shows a somewhat different embodiment which does not comprise a central unit control unit 43 as shown in FIG. 4 but a number of decentral unitized control units 48 located in proximity of one or several of the illustrated consumer locations 45 so that these locations are the only ones to be controlled.

As previously mentioned, the data may be transmitted via the information system 5 which may consist of wired or wireless connections. In addition, when the issue is one of electrical supply in particular, it is possible to transmit the data via the supply system 41, e.g. in the form of superimposed signals.

As is apparent from the previous, such installation systems may be utilized in connection with consumption and/or distribution/production of various forms of consumption such as electricity, heat, water, gas etc. and/or combinations hereof. It will be apparent that the described embodiments only serve to illustrate the invention and that the invention may comprise several variations obvious to a man skilled in the art without parting from the scope of the claims below.

1. Method of use in relation to control of production and/or consumption in a distribution system (1) of for example heat, electricity, gas, water etc., or in a system or associated systems comprising at least one producer or distributor (3) and one or more consumers (2), characterized b y information of for example purchase and/or sales prices or prognoses thereof, tariffs etc. of importance to the consumption and/or production, being provided to one or more of said consumers (2), producers and/or suppliers (3), and by said information being used to control production, delivery and/or consumption, and by said information comprising:
actual and/or determined data concerning a first period of time, and
expected, calculated and/or estimated data concerning a second period of time,
said first period of time being identified as the period of time following immediately after the time of consumption and/or production, and said second period of time extending beyond said first period of time.

2. Method according to claim 1 characterized by said information comprising time-sequential information (6) which is a function that relates to the determined or expected development in sales prices for a well-defined part of the future.

3. Method according to claim 1 or 2 characterized by said information comprising time-sequential information (7) which is a function that relates to the determined or expected development in purchase prices for a well-defined part of the future.

4. Method according to claim 1, 2 or 3 characterized by said information comprising time-sequential information (6) which is a function that relates to the meteorological parameters of importance to the producers or the consumers when planning ahead for a well-defined period of the future.

5. Method according to claims 1 to 4, characterized by said information being utilized by one or more consumers for time-dependent control of switching-on and/or regulation of consumption for one or more units at each consumer.

6. Method according to one or more of claims 1 to 5, characterized by said information comprising service messages to producers and/or consumers.

7. Method according to one or more of claims 1 to 6, characterized by said information being utilized by one or more of said producers for time-associated control of initiation and/or regulation of one or more units at each producer.

8. Method according to one or more of claims 1 to 7, characterized by said time-sequential information (8) which is a function that relates to determined or expected plans for future production being transmitted from one or more consumers (2) to a central unit (4).

9. Method according to one or more of claims 1 to 8, characterized by said time-sequential information (8) which is a function that relates to determined or expected plans for future production being transmitted from one or more producers (3) to a central unit (4).

10. Method according to one or more of claims 1 to 7, characterized by one or more of said consumers (2) also being producers/suppliers (3).

11. System for use in connection with the control of production and/or consumption in a distribution system (1) of for example heat, electricity, gas, water etc. or in a system or associated systems comprising at least one producer or supplier (3) and one or more consumers (2) characterized by the system using a method according to one or more of claims 1 to 10.
